(19) United States
(12) Patent Application Publication
(10) Pub. No.: US 2026/0169108 A1
(43) Pub. Date: Jun. 18, 2026

(54) Shim Parameter Set Ascertainment for a Magnetic Resonance Facility

(71) Applicant: Siemens Healthineers AG, Forchheim (DE)

(72) Inventor: Stephan Biber, Erlangen (DE)

(73) Assignee: Siemens Healthineers AG, Forchheim (DE)

(21) Appl. No.: 19/419,502

(22) Filed: Dec. 15, 2025

(30) Foreign Application Priority Data
Dec. 16, 2024 (DE) 10 2024 211 959.8

(51) Int. Cl. G01R 33/3875

(52) U.S. Cl. CPC G01R 33/3875

(57) ABSTRACT

A method is provided for ascertaining a shim parameter set for shimming a magnetic resonance (MR) facility to improve magnetic field homogeneity within a homogeneity volume. The method includes receiving an input data set comprising a current magnetic field measurement of the MR facility and accessing a database storing source data sets associated with MR facilities for which shim operations have been completed at respective operating locations. Each source data set comprises a magnetic field measurement acquired prior to the shim operation and shim parameters determined as a final result of the shim operation while accounting for location-specific magnetic influences. The method further includes ascertaining the shim parameter set by applying an ascertainment function to the input data set and the source data sets, wherein the ascertainment function accounts for local magnetic influences using the stored source data sets and outputs an output data set comprising the shim parameter set.

### TECHNICAL FIELD

The disclosure relates to a computer-implemented method and an ascertainment facility for ascertaining a shim parameter set which describes the use of, in particular, passive, shim facilities for shimming of a magnetic resonance facility to be shimmed in order to improve the homogeneity in a homogeneity volume, an ascertainment function being used which ascertains an output data set comprising the shim parameter set from an input data set comprising at least one current measurement result of a magnetic field measurement at the magnetic resonance facility to be shimmed. In addition, the disclosure relates to a method for the installation of a magnetic resonance facility at an operating location, a computer program, and an electronically readable data medium.

### BACKGROUND

The homogeneity in a homogeneity volume used for recording magnetic resonance data is extremely important in modern magnetic resonance facilities. In order to obtain a best possible homogeneity, after assembly at an operating location the magnetic resonance facility is shimmed, which means that the homogeneity in the homogeneity volume is improved by the use of shim facilities to such an extent that a desired target homogeneity is obtained, in particular, a homogeneity condition is fulfilled. The basic magnetic field (B0 field) should therefore be optimized to a specific target value in terms of strength and deviation via the homogeneity volume.

At least initially during installation, passive shim facilities are customarily used, which provide the arrangement of magnetic material, in particular, shim elements referred to as shim irons, at the magnetic resonance facility. For this purpose, carrier facilities with appropriate receptacles, so-called shim trays, in particular, with pockets for the shim elements, can be provided. For example, such carrier facilities can be provided in the area of a gradient coil arrangement surrounding a patient receptacle. Active shim facilities, such as, for example, shim coils, are often used for detailed corrections and/or to respond to changes during operation.

In this context, shimming of the magnetic resonance facility is also necessary at the operating location provided for its operation, that is to say, after its assembly during installation. On the one hand, it is necessary to compensate for the remaining tolerances of the manufacturing process, in particular, with regard to the superconducting main magnet providing the basic magnetic field, while on the other hand, the magnetic environment at the operating location has an effect on the homogeneity of the homogeneity volume. Examples of such magnetic influences at the operating location include iron girders in the structure of the building, specifically designed large iron shields, and larger iron structures in the vicinity, for example, railway tracks. All these magnetic elements, in particular, iron elements, have an influence on the distribution of the magnetic field in the homogeneity volume, that is to say, the imaging volume, of the magnetic resonance facility.

Present-day shim operations are characterized by the problem that measuring the homogeneity of the basic magnetic field in the homogeneity volume is only possible with an active superconducting main magnet which must be started up over a long period of time, while the adjustment of the shim facilities can only be carried out when the superconducting main magnet, which must be shut down or ramped down over a long period of time, is inactive, as otherwise shim elements, for example shim irons, could not be used due to the high forces involved.

It is known in the prior art to first start up the main magnet, thus generating the basic magnetic field as in the operating state. Thereafter, using a measuring facility, for example, a so-called “array shim device”, the distribution of the basic magnetic field in the homogeneity volume and thus its homogeneity is measured in order to obtain an original measurement result. In particular, the field distribution is measured at various individual positions on the surface of a sphere, with particularly accurate measurements possible thanks to a measurement process carried out by the magnetic resonance facility on so-called field samples, for example, small water-filled cylinders which can be wrapped with a coil. Alternatively, Hall sensors can also be used. The measurement data of the original measurement result is used to ascertain a test shim parameter set by means of a magnetostatic calculation. The main magnet is then shut down again, and the test shim parameter set, which may describe, for example, a shim iron distribution, is implemented at the shim facilities. The main magnet is then started up again, and the field distribution is measured again. The new measurement result is checked by a homogeneity condition, which describes the achievement of the target homogeneity. In about half of the cases, the homogeneity condition is not fulfilled, so that based on the new measurement result, a further test shim parameter set is ascertained by magnetostatic calculation, the magnet is shut down again, the test shim parameter set is implemented, and after starting up again, it must be measured again.

The reason for this frequent need for iteration is that the magnetic interactions of the shim facilities, the main magnet, and the magnetic environment cannot be calculated sufficiently accurately to ensure that the shim parameters, in particular, the shim iron allocation, can always be predicted successfully after the first iteration. In particular, information on magnetic influences in the environment at the operating location is usually not known or not known with sufficient accuracy and therefore cannot be taken into account when calculating the test shim parameter set. The homogenization function used for this purpose is primarily based on magnetostatic calculations, which do not allow for an exact prediction of suitable shim parameters, as
the accuracy requirements are very high, as the homogeneity in the range of ppm or even less than one ppm must be ensured, and tolerances are therefore problematic,
the magnetic influences of the environment of the magnetic resonance facility at the operating location of the homogeneity function are not known (this is a systematic problem because the interaction of the main magnet and the shim facilities with the environment cannot be taken into account), and
the measurement result only shows how the magnetic environment, together with the manufacturing tolerances, affects the basic magnetic field, but it is not known which effect has which cause.

If further iterative steps are necessary, the shim operation at the operating location is significantly prolonged, exacerbating the problem with main magnets, which are cooled with little coolant, in particular, helium, in a closed circuit (so-called dry magnets). Starting up a “wet” magnet at 3 tesla takes approximately one hour on its own. The shim operation with two iterations then usually requires a whole day in the installation. This creates costs for the service technician and delays the start of the clinical use of the magnetic resonance facility. The problem is further exacerbated in the case of main magnets, as the current must be started up more slowly during shimming as a result of the limited heat capacity in dry main magnets. This reduces the heat input caused by the change in the main magnetic field by slowing it down. This significantly increases the amount of work required again, so that a second working day may be necessary for a shim operation with two or more iterative steps.

### SUMMARY

An object underlying the aspects of the disclosure is therefore to make shim operations at least statistically more time and cost-efficient.

This object is achieved according to the disclosure by a computer-implemented ascertainment method, an installation method, an ascertainment facility, a computer program, and an electronically readable data medium as claimed in the secondary claims. Advantageous developments will emerge from the subclaims.

In a method of the type mentioned at the outset, it is provided according to the disclosure that, in order to ascertain the shim parameter set by means of the ascertainment function, a database is maintained in which source data sets are stored for magnetic resonance facilities installed at an operating location, for which a shim operation has been completed at the operating location, which comprise an original measurement result of a magnetic field measurement prior to the shim operation at the operating location and the shim parameters obtained as the final result of the shim operation at the operating location, which were ascertained taking into account magnetic influences at the respective operating location.

The specific aspects mainly relate to passive shim facilities in which the shim parameter set describes, in particular, the properties and the arrangement of at least one shim element, in particular, at least one shim iron, and one passive shim facility. In principle, however, it is also applicable to other types of shimming, for example, in the case of at least partial use of active shim facilities such as, for example, shim coils.

According to the disclosure, it is proposed, using the database, to provide and use information from a multiplicity of previous shim operations, in particular, those which have actually been carried out, but also virtual shim operations if necessary, in order to significantly increase the probability of achieving the target of the shim operation, i.e., target homogeneity, with the first shim parameter set determined by the ascertainment function. The shim parameters are therefore not primarily derived from magnetostatic calculations but use prior knowledge from magnetic resonance facilities already installed at operating locations and/or virtual shim operations. The database can preferably contain at least 500, preferably at least 1000, source data sets. This therefore represents a “big data” approach which, in particular, allows significant improvements in the estimation of shim parameters, particularly on a statistical basis. In other words, the statistical data that can be used as a result of the big data approach increases the likelihood that, after the first iteration, a shim parameter set will be found that is sufficient to avoid a second iteration. Findings from previous shim operations are therefore used to avoid making the same mistake multiple times.

As there are usually major differences between different models or types of magnetic resonance facilities, it may be expedient for the database to refer to a predetermined model and/or a predetermined type of magnetic resonance facility. In other words, all the magnetic resonance facilities of the source data sets refer to the same model or the same type for which the shim parameter set is to be determined by means of the ascertainment function. The design of the magnetic resonance facility is thus at least essentially the same, at least in terms of the field-generating and field-influencing components.

It should be noted at this point that taking into account magnetic influences at the respective operating location also includes an iteration having been terminated on account of the termination condition being fulfilled after an iterative step, because these magnetic influences are taken into account at the latest by the new measurement after implementing the shim parameters and checking whether sufficient homogeneity (i.e., the target homogeneity) has been achieved, even if for at least some of the source data sets the calculation of the shim parameters took place on a magnetostatic basis without specific consideration of the environment at the operating location.

The measurement result can be recorded using a measuring facility, for example, a so-called “array shim device”, and shows the distribution of the basic magnetic field in the homogeneity volume and thus its homogeneity. In particular, the field distribution can be measured by means of measurements at various individual positions on the surface of a sphere, with particularly accurate measurements possible thanks to a measurement process carried out by the magnetic resonance facility on so-called field samples, for example, small water-filled cylinders which can be wrapped with a coil. Alternatively, Hall sensors can also be used.

As already mentioned, it may be particularly advantageous to ensure that at least some of the source data sets relate to shim operations that have actually been carried out in practice at the respective operating location. Reference is therefore made to previous installations, which may include both (if necessary, however, multi-step) shim operations using the ascertainment function and conventional shim operations. The broadest possible data base is thus provided, which grows continuously, in particular, in the case of preferable regular updating of the database and thus improves the reliability of the output data sets of the ascertainment function as it can constantly learn from shim operations already undertaken.

Specifically, it may be provided that at least in part in the shim operations for ascertaining the source data sets, the shim parameter set was iteratively improved by analytically ascertaining test shim parameters sets in each iterative step from the preceding measurement result be means of an optimization function which does not take into account magnetic influences at the respective operating location and which, in particular, comprises a magnetostatic calculation, and after implementing the test shim parameters sets, a new magnetic field measurement was performed, the shim operation being terminated when a new measurement result indicated sufficient homogeneity in the homogeneity volume. This means that, at least for some of the source data sets, the approach described at the outset, which uses magnetostatic calculations and does not directly include magnetic influences of the environment at the operating location, can be used. However, the verification and further iterative steps carried out in case of doubt ensure that the environment is sufficiently taken into account for the final iteration result to provide sufficient homogeneity in the homogeneity volume.

However, it may also be provided that, for at least some of the source data sets, the shim parameters are ascertained by means of a calculation, in particular, a simulation, taking into account information describing magnetic influences at the respective operating location. In particular, for enhancing and enlarging the database, but in less preferred exemplary aspects also as the sole basis, the results of magnetostatic and/or other simulations, which map magnetic tolerances and the environment at the operating location in a particularly large number of scenarios, can also be used to form source data sets. Consequently, virtual scenarios with virtual shim operations can also be used, in which, for example, tolerances in the manufacture of the magnetic resonance facility and/or magnetic influences of the environment at the operating location are varied.

In a particularly advantageous development of the aspects of the present disclosure, it can be provided that at least some of the source data sets and the input data set may comprise additional shim information describing a shim operation at a manufacturing location at which a predefined environment with regard to magnetic influences exists, which is also used for ascertaining the shim parameter set by means of the ascertainment function. In many magnetic resonance facilities, an initial shim operation is already carried out at a manufacturing location in defined environments, i.e., including defined magnetic influences. Such additional shim data from the manufacture of the magnetic resonance facility may, when taken into account, allow manufacturing-related tolerances and their effects to be at least implicitly separated from effects of the environment at the operating location. If, for example, data sets in the additional shim information (i.e., basic manufacturing tolerance) and in the measurement result at the operating location correspond or are very similar, it may be assumed with greater probability that comparable magnetic influences of the environment exist at the operating location, as there are already similarities with regard to the manufacturing tolerances. Preferably, the additional shim information may also include an original measurement result and shim parameters for the shim operation at the manufacturing location.

In principle, various specific variants for the use of the database are possible. A first, specific alternative aspect provides that the ascertainment function ascertains a similarity measure of the input data to corresponding source data of the source data sets, which describes at least one similarity of the current measurement result of the input data set to the original measurement result of the source data set, the ascertainment function retrieving the shim data of the source data set with the highest similarity measure from the database and outputting it as the shim parameter set of the output data set. The ascertainment function, therefore, searches for a source data set from the database in which the measured field distribution, i.e., the local original measurement result, comes closest to the currently measured field distribution, i.e., the current measurement result. Once the shim data, for example, a shim iron allocation which has resulted in success there, is known from the source data set, this shim data can now also be used for the current magnetic resonance facility to be shimmed. Suitable similarity measures for comparing the original measurement result and the current measurement result are already known in the prior art.

In this context, it may be particularly advantageous to provide that the similarity measure additionally describes a similarity of the additional shim information. In other words, the similarity measure then describes not only that the measurement results at the operating location are comparable, but also that the measurement results and the shimming at the manufacturing location for the magnetic resonance facility to be shimmed and the magnetic resonance facility of the source data set are comparable. With such an approach, the predefined environment at the manufacturing location makes it easier to separate manufacturing tolerance effects and environmental effects, and the probability is further increased that the proposed shim data from the most similar source data set will result in success after the first iteration. In other words, it is more probable that with comparable manufacturing tolerances, comparable magnetic influences from the environment will also be present at the start of the shim operation at the operating location as a result of the equally comparable measurement results. The various contributions can be weighted equally in the similarity measure, but they can also be weighted differently. For example, an at least slightly higher value can be attached to the match at the start of the shim operation at the operating location.

In principle, it is conceivable that an item of magnetic resonance facility information describing at least one property of the magnetic resonance facility to be shimmed might also be used as input data, the source data sets also describing at least one item of magnetic resonance facility information, and the similarity measure also describing a similarity between the items of magnetic resonance facility information. On the one hand, this is useful if a database is used for several types and/or models of magnetic resonance facilities, as the appropriate source data sets can then be selected. In other words, the magnetic resonance facility information may relate to a type and/or model of magnetic resonance facility. However, it is also possible to incorporate manufacturing tolerances in other ways via magnetic resonance facility information, for example, by the magnetic resonance facility information relating to at least one design property that exerts influence on the main magnetic field. The design property may, for example, indicate a deviation from a specification that occurred during manufacture, i.e., a manufacturing tolerance. However, it is preferable to use the additional shim information.

In an expedient development the first alternative aspect, it may be provided that the similarity measure is modified by an optimization term, the optimization term relating to an additional optimization target which is at least partially described by the source data sets. It is also expedient to select a suitable weighting for such optimization terms. The optimization target can, for example, relate to reducing material and labor costs. For example, a shim configuration can be selected as an optimization target such that as few shim elements or as little material as possible are required overall. Another exemplary optimization target may require that changes be made to as few shim facilities or locations of the magnetic resonance facility as possible.

In a second, specific alternative aspect, it may be particularly advantageous that a trained ascertainment function which is trained using the source data sets of the database is used. It is therefore proposed to use techniques of artificial intelligence in order to make optimal use of the database and the knowledge contained therein. To this end, the ascertainment function is trained using machine learning by means of the source data sets in the database. This means, in particular, that it is no longer necessary to maintain or provide the database directly at each operating location as the ascertainment function has learned the correlations and stored what it has learned using the corresponding parameters of the trained ascertainment function. This approach is particularly advantageous as the trained ascertainment function can directly learn the weighting of the individual measured values of the original measurement result, in particular, the measured values on the surface of the sphere, for the shim parameter set, whereas a pure “look-up” approach can only take into account the similarity of the individual measured values, but does not take into account the weighting of the measured values when selecting the correct source data set. Therefore, improved results improved in this way can be achieved. Particularly advantageously, the training is also based both on the original measurement and on the additional shim information in order to map the correlations which this involves and achieve a further improvement in quality.

Also conceivable in the context of the present disclosure is a computer-implemented method for providing a trained ascertainment function which ascertains from an input data set, at least comprising a current measurement result of a magnetic field measurement on a magnetic resonance facility to be shimmed, an output data set comprising a shim parameter set which describes the use of shim facilities for shimming the magnetic resonance facility in order to improve the homogeneity in a homogeneity volume, comprising the following steps:
provision of a database in which source data sets are stored for magnetic resonance facilities installed at an operating location for which a shim operation has been completed at the operating location, which comprise an original measurement result of a magnetic field measurement prior to the shim operation at the operating location and the shim parameters obtained as the final result of the shim operation at the operating location, which were ascertained taking into consideration magnetic influences at the respective operating location,
ascertainment of training data sets from the source data sets, the original measurement results being entered into the training input data sets and the shim parameters being entered into the training output data sets as fundamental truth,
training of the ascertainment function using the training data sets, and
provision of the trained ascertainment function.

A corresponding provisioning system, a provisioning computer program and an electronically readable data medium on which the provisioning computer program is stored are also conceivable.

In general, a trained function maps cognitive functions which humans associate with other human brains. Through training based on training data (machine learning), the trained function is able to adapt to new circumstances and to detect and extrapolate patterns. Another term for “trained function” is “trained machine learning model”.

Generally speaking, the parameters of a trained function can be adjusted by means of training. In particular, supervised learning, semi-supervised learning, unsupervised learning, reinforcement learning, and/or active learning can be used. Furthermore, representation learning (also known as “feature learning”) can be used. The parameters of the trained function can be adjusted iteratively, in particular, by means of several training steps. In particular, a specific cost function can be minimized during training. For example, when training a neural network, the backpropagation algorithm can be used.

A trained function may comprise, for example, a neural network, a Support Vector Machine (SVM), a decision tree, and/or a Bayes network, and/or the trained function can be based on k-means clustering, Q-learning, genetic algorithms, and/or assignment rules. In particular, a neural network can be a deep neural network, a convolutional neural network (CNN), or a deep CNN. Furthermore, the neural network can be an adversarial network, a deep adversarial network, and/or a generative adversarial network (GAN).

A convolutional neural network (CNN) is a neural network that uses a convolution operation instead of general matrix multiplication in at least one of its layers, the so-called convolution layer. In particular, a convolution layer can perform a scalar product of one or more convolution kernels with the incoming data/images of the convolution layer, the entries of the one or more convolution kernels being the parameters or weights which are adjusted by means of training. In particular, the Frobenius inner product and the ReLU activation function can be used. A CNN can include additional layers, for example, pooling layers, fully connected layers, and normalization layers.

As for the trained ascertainment function, this can include a neural network, in particular, a CNN. Other architectures are also conceivable.

In an expedient development of the second alternative aspect, it may be provided that at least one optimization target that relates to a situation described by the source data sets is also included in the training of the ascertainment function. For example, the optimization target can also be included as a boundary condition and/or in a loss function. As already described above with regard to the first design variant, optimization targets may relate in particular, to material and/or cost in the shim operation. For example, an optimization target can be the minimization of material consumed and/or the minimization of the number of shim facilities to be adjusted.

It should be noted that other statistical approaches, which extract statistical information used by the ascertainment function from the database, are also conceivable in addition to or as an alternative to.

An expedient development of the aspects of the present disclosure may provide that, prior to implementation of the shim parameter set obtained as the output data set of the ascertainment function, a comparison shim parameter set is ascertained from the current measurement result by means of an optimization function which does not take into account magnetic influences at the respective operating location and is used to check the plausibility of the shim parameter set of the ascertainment function. The previous, in particular, magnetostatic, calculation can thus be introduced as a kind of test step to ascertain whether the shim parameter set of the initial data of the ascertainment function has a meaningful effect. Errors can be avoided in this way.

In addition to the ascertainment method, the present disclosure also relates to an installation method, therefore a method for installing a magnetic resonance facility at an operating location, a shim parameter set being ascertained with an ascertainment method according to the disclosure, and the shim facilities being configured according to the shim parameter set. All the aspects with regard to the ascertainment method according to the disclosure can be applied analogously to the installation method according to the disclosure and vice versa, so that the advantages already mentioned can also be obtained with the installation method.

It is particularly expedient if, after configuring the shim facilities according to the shim parameter set, a new magnetic field measurement is performed to obtain a new measurement result, and the new measurement result is evaluated by a homogeneity condition. As already explained, the homogeneity condition describes whether the target homogeneity has been obtained (if it is fulfilled) or not (if it is not fulfilled). If the homogeneity condition is not fulfilled, it may also be expedient to proceed iteratively in the context of the aspects of the present disclosure, it being entirely possible to apply the ascertainment function several times. However, as a systematic error may be present, it may also be expedient to return to the previous method (with the improved starting point according to the output data set of the first iterative step).

In an expedient development of the installation method, it may therefore be provided that, after applying the shim parameters described by the output data set, the new measurement result of the new magnetic field measurement is evaluated by the homogeneity condition, wherein, in the event of the homogeneity condition not being fulfilled by the new measurement result, the shim parameter set is iteratively improved by analytically determining a test shim parameter set in each iterative step from the previous measurement result by means of an or the optimization function, which does not take into account magnetic influences at the respective operating location and in particular, comprises a magnetostatic calculation, and after implementation of the test shim parameter set, a new magnetic field measurement is performed, wherein the shim operation is terminated when a new measurement result fulfills the homogeneity condition. In this manner, if the ascertainment function does not yet provide conclusively suitable shim parameters in a rare case, an improvement can be achieved in at least one further step using the conventional approach.

Not only with regard to cases in which rectification is carried out using the conventional approach, but also in other applications of the installation method according to the disclosure, after completion of the shim operation, it is expedient to add a source data set from this shim operation to the database. In this manner, the database is always kept as up-to-date as possible. In the second alternative aspect, the trained ascertainment function can be further trained with new source data sets and thus improved. In this manner, the best possible data base is always used.

The disclosure further relates to an ascertainment facility for ascertaining a shim parameter set which describes the use of, in particular, passive, shim facilities for shimming a magnetic resonance facility to be shimmed in order to improve the homogeneity in a homogeneity volume, comprising an application unit for applying an ascertainment function to an input data set, the input data set comprising at least one current measurement result of a magnetic field measurement on the magnetic resonance facility to be shimmed, in order to ascertain an output data set comprising the shim parameter set. According to the disclosure, the ascertainment facility also comprises a usage unit for using a database to ascertain the shim parameter set by means of the ascertainment function, source data sets being stored in the database for magnetic resonance facilities installed at an operating location for which a shim operation has been completed at the operating location, which comprise an original measurement result of a magnetic field measurement prior to the shim operation at the operating location and the shim parameters obtained as the final result of the shim operation at the operating location, which were ascertained taking into account magnetic influences at the respective operating location. All aspects with regard to the method according to the disclosure, in particular, the ascertainment method, can be transferred analogously to the ascertainment facility according to the disclosure and vice versa, so that the aforementioned advantages can also be achieved with the ascertainment facility.

The ascertainment facility may, in particular, comprise at least one processor and at least one storage medium. Hardware and/or software form functional units in order to perform the steps of the method according to the disclosure. In the case of the first alternative aspect, the usage unit may, for example, be a supply unit that grants the ascertainment function access to the database for determining the similarity measure. In the second alternative aspect, the usage unit may be a training unit that is designed to train the ascertainment function using the source data sets of the database. As already mentioned, the usage unit may also be or comprise a general statistical unit. Of course, other functional units are also conceivable for performing aspects of the ascertainment method according to the disclosure, for example, a plausibility unit for plausibility checking based on magnetostatic calculations.

The ascertainment facility may, for example, be designed as a mobile device that a service technician can carry with them when installing magnetic resonance facilities at corresponding operating sites. For example, the ascertainment facility may be a specially configured tablet.

An ascertainment computer program according to the disclosure can be loaded directly into a storage medium of an ascertainment facility and has program means such that, when the computer program is executed on the ascertainment facility, the latter is caused to perform the steps of an ascertainment method according to the disclosure. The computer program can be stored on an electronically readable data medium according to the disclosure, which thus has stored control information that comprises at least one computer program according to the disclosure and is designed in such a manner that, when the data medium is used in an ascertainment facility, the latter is designed to carry out an ascertainment method according to the disclosure. The data medium may, in particular, be a non-transient data medium, for example a CD-ROM.

### BRIEF DESCRIPTION OF THE DRAWINGS

Further advantages and details of the aspects of the present disclosure will emerge from the exemplary aspects described hereinafter and with reference to the drawings, in which:

FIG. 1 shows a flow chart of a first exemplary aspect of the ascertainment method according to the disclosure,

FIG. 2 shows a flow chart of a second exemplary aspect of the ascertainment method according to the disclosure,

FIG. 3 shows a flow chart of an installation method according to the disclosure, and

FIG. 4 shows the functional design of an ascertainment facility according to the disclosure.

### DETAILED DESCRIPTION

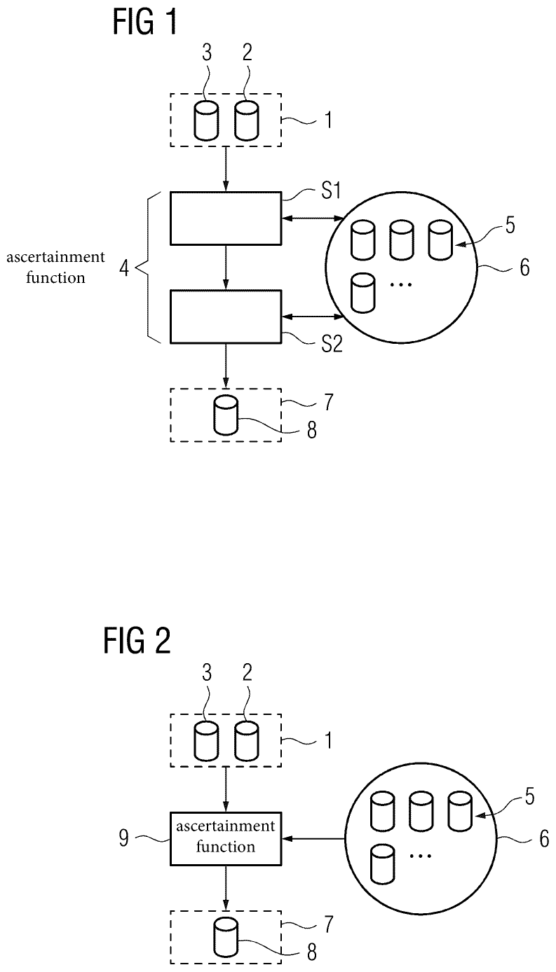

FIG. 1 shows a flow chart of an exemplary aspect of the ascertainment method according to the disclosure in the first alternative aspect. The aim is to ascertain a shim parameter set 8 for existing passive shim facilities of a magnetic resonance facility to be shimmed at an operating location. This means that the magnetic resonance facility is basically ready for operation at the operating location, and it only remains for the shim configuration to be selected so that a homogeneity condition for the homogeneity of the basic magnetic field in a homogeneity volume of the magnetic resonance facility is fulfilled. This takes place in a shim operation, in this case, an initial shim operation having already been performed at a manufacturing location at which only predetermined magnetic influences from the environment were present. In this initial shim operation, manufacturing tolerances were therefore mainly compensated. An original measurement result of the shim operation at the manufacturing location and the result of the first shim operation at the manufacturing location, i.e., shim data from the manufacturing location, are available as additional shim information 2.

In order to ascertain a shim parameter set 8, which preferably provides a final shim configuration that fulfills the homogeneity condition in a single iterative step, for the shim operation at the operating location at which other magnetic influences of the environment are present, an input data set 1 is first compiled. Besides the additional shim information 2, the input data set 1 in this case also comprises a current measurement result 3, i.e., a measurement data set, at the operating location, which was recorded at the start of the shim operation. For this purpose, a measuring facility can be used, for example, which measures the magnetic field at various points on the surface of a sphere when the main magnet is started up, thus when the basic magnetic field is present. For example, field samples can be used in a measurement process that uses a magnetic resonance sequence of the magnetic resonance facility for magnetic field measurement.

The input data of the input data set 1 is transferred to an ascertainment function 4, which, in a first step S1, ascertains a similarity measure with regard to a plurality of source data sets 5 in a database 6. Each source data set 5 describes a shim operation which has already been completed and is preferably real, if necessary however, also partially virtual, of a magnetic resonance facility at a corresponding operating location and on the one hand, contains an original measurement result of the shim operation at the operating location as well as the shim parameter set which was ultimately used there to configure the shim facilities and led to the fulfillment of the homogeneity condition and, on the other hand the additional shim information of the manufacturing location assigned to the respective magnetic resonance facility. The shim parameter set of a respective source data set was finally ascertained taking into account the magnetic influences of the environment at the operating location, for example in an iterative approach in which, in each iterative step a test shim parameter set was ascertained and applied from the most recently recorded measurement result by means of magnetostatic calculation without taking into account the magnetic influences of the environment at the operating location, the process being terminated after application if the homogeneity condition for a measurement result was fulfilled, as a result of which the magnetic influences of the environment at the operating location are also included in the final shim result of the shim operation. However, the source data sets may also result from an earlier application of the ascertainment function 4 (or with regard to FIG. 2 of the ascertainment function 9) or be analytically ascertained, for example, by means of a simulation which also used influence information describing the magnetic influences of the environment at the operating location of the respective real or imagined magnetic resonance facility.

The database 6 gathers experience or prior knowledge, so to speak, for shim operations at operating locations.

In order to ascertain the similarity measure, in the present case, a partial measure is ascertained with regard to the similarity of the respective original measurement result and the current measurement result 3, and a further partial measure is ascertained with regard to the similarity of the additional shim information of the respective source data set 5 and the additional shim information 2 of the input data set 1. The partial measures can be weighted or unweighted and added together to obtain the similarity measure. In addition, the similarity measure can also comprise an optimization term describing an optimization target, which also draws on information contained in the source data sets 5. If, for example, the optimization target is to keep the amount of material, here shim irons for example, as low as possible, the optimization term can be a penalty term which increases with the amount of material specified in the corresponding source data set 5. Here too, relative weighting is of course possible, in particular, in comparison with the partial measures.

In a step S2 of the ascertainment function 4, the shim data of that source data set 5 in which the greatest similarity measure is present is then retrieved from the database 6 and output as at least part of an output data set 7. The output data set 7, therefore, contains at least the shim parameter set 8, which is to be applied to the magnetic resonance facility to be shimmed.

As a result of also taking into account the similarity of the additional shim information in a partial measurement, both the similarity with regard to the manufacturing tolerances (described by the additional shim information) and the similarity with regard to the magnetic influences of the environment (contained in the current measurement result 3 and the original measurement result) can be maximized and separated from one another in order to find particularly suitable shim parameters in the database 6.

FIG. 2 shows a flow chart of an exemplary aspect of the method according to the disclosure in the second alternative aspect. As in the first exemplary aspect, the database 6 and the input data set 1 are used to derive an output data set 7 with a shim parameter set 8, but instead of the ascertainment function 4, which did not use artificial intelligence, a trained ascertainment function 9 comprising at least one neural network, in particular, a CNN, is used. The ascertainment function 9 was trained using the source data sets 5 of the database 6 in order to infer output data sets 7 from input data sets 1. For this purpose, training input data sets were formed from the additional shim information and the original measurement results of the respective source data sets 5, and training output data sets were formed from the shim parameters of the respective source data sets 5 as fundamental truth and used for training. At least one optimization target can also be taken into account during training.

In this manner, it is not necessary to provide the database 6 during installation at the operating location, but it does make sense to keep the trained ascertainment function 9 up to date by regularly retraining it using new source data sets 5 added to the database 6.

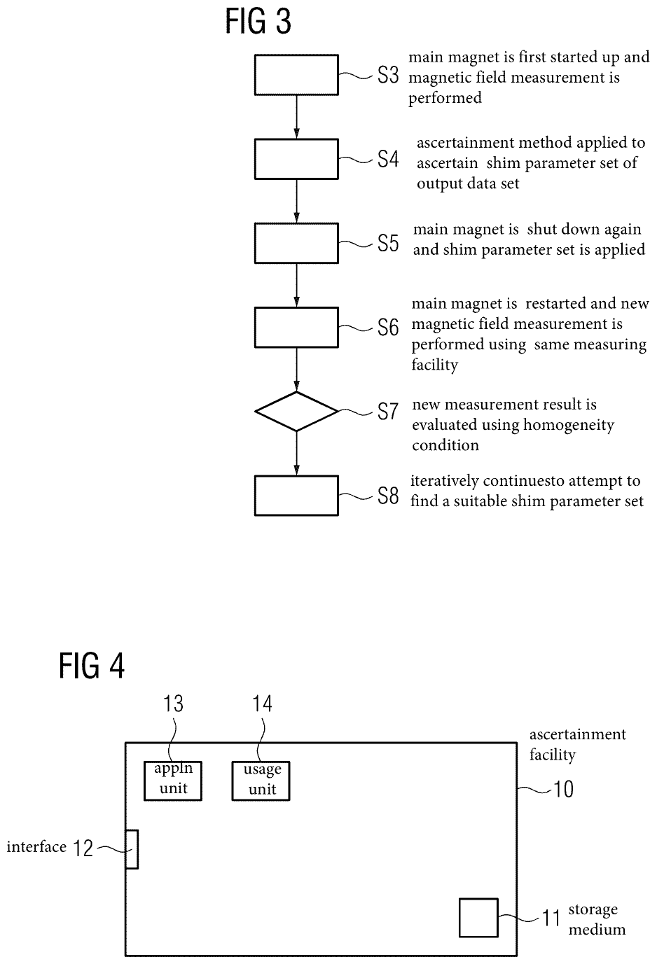

FIG. 3 shows a flow chart of an exemplary aspect of the installation method according to the disclosure, specifically for performing a shim operation on a magnetic resonance facility to be shimmed at an operating location. In a step S3, the main magnet of the magnetic resonance facility is first started up, and the magnetic field measurement is performed, which leads to the current measurement result 3. In a step S4, the ascertainment method in the first alternative aspect or the second alternative aspect according to FIG. 1 or FIG. 2 is applied to ascertain the shim parameter set 8 of the output data set 7. In step S5, the main magnet is then shut down again, and the shim parameter set is applied.

At this point, it should be noted that in the exemplary aspects described here, which relate to passive shim facilities, the shim parameter set 8 describes an assignment with shim elements, specifically a shim iron allocation. These can only be inserted into corresponding receptacles, for example, pockets on shim trays.

In a step S6, the main magnet is then restarted, and a new magnetic field measurement is performed using the same measuring facility, and a new measurement result is obtained. This new measurement result is evaluated in a step S7 using the homogeneity condition. If this condition is fulfilled, there is sufficient homogeneity, and the target homogeneity has been achieved. The shim operation and thus the installation method can then be terminated.

However, if the homogeneity condition in step S7 is not fulfilled, step S8 iteratively continues to attempt to find a suitable shim parameter set. In this case, the ascertainment function 4, 9 is not used again, but instead the conventional magnetostatic calculation is employed, which does not take into account the magnetic influences of the environment.

It should also be noted that before applying the shim parameter set 8 in step S5, a plausibility check can also be performed using the conventional magnetostatic calculation mentioned above. In this case, a comparison shim parameter set can be ascertained and compared with the shim parameter set 8, it being possible, in the event of implausibility, to use the comparison shim parameter set instead of the shim parameter set 8, for example.

FIG. 4 finally shows a functional schematic outline of an ascertainment facility 10 according to the disclosure. The ascertainment facility 10 firstly comprises a storage medium 11 in which, for example, the database 6 and/or the ascertainment function 4, 9, which may be trained, can be stored. A wide variety of other data and information used in the methods described can also be stored there.

The ascertainment facility 10 comprises an interface 12 via which, for example, additional shim information 2 and/or current measurement results 3 can be received and/or the shim parameter set 8 can be output. In an application unit 13, the ascertainment function 4, 9 is then applied to the input data set 1. The usage unit 14 controls the use of the database 6. In the first alternative aspect (FIG. 1), this may be a supply unit that allows the ascertainment function 4 to access the database 6. In the second alternative aspect (FIG. 2), this may be a training unit for training the ascertainment function 9.

Additional functional units, for example, a plausibility check unit, are also conceivable.

Independent of the grammatical term usage, individuals with male, female or other gender identities are included within the term.

1. A computer-implemented method for ascertaining a shim parameter set for shimming a magnetic resonance facility to improve homogeneity in a homogeneity volume, the method comprising:
receiving an input data set comprising at least one current measurement result of a magnetic field measurement at the magnetic resonance facility;
maintaining a database in which source data sets are stored for magnetic resonance facilities installed at an operating location for which a shim operation has been completed at the operating location, wherein each source data set comprises:
an original measurement result of a magnetic field measurement prior to the shim operation at the operating location, and
shim parameters obtained as a final result of the shim operation at the operating location, the shim parameters having been ascertained considering magnetic influences at the respective operating location; and
ascertaining the shim parameter set by applying an ascertainment function to the input data set and the source data sets, wherein the ascertainment function accounts for local magnetic influences using the source data sets and outputs an output data set comprising the shim parameter set.

2. The method as claimed in claim 1, wherein at least some of the source data sets relate to shim operations carried out in practice at the respective operating location.

3. The method as claimed in claim 1, wherein, at least in part, the shim parameter set was iteratively improved in the shim operations for ascertaining the source data sets by test shim parameter sets having been analytically ascertained in each iterative step from a previous measurement result, using an optimization function which does not take into account the magnetic influences at the respective operating location, and after implementation of the test shim parameter sets, a new magnetic field measurement was performed, wherein the shim operation was terminated when a new measurement result indicated sufficient homogeneity in the homogeneity volume.

4. The method as claimed in claim 1, wherein, for at least some of the source data sets, the shim parameters are ascertained by a calculation taking into account influence information describing magnetic influences at the respective operating location.

5. The method as claimed in claim 1, wherein at least some of the source data sets and the input data set comprise additional shim information describing a shim operation at a manufacturing location at which a predefined environment with regard to magnetic influences exists, and the additional shim information is also used for the ascertainment of the shim parameter set using the ascertainment function.

6. The method as claimed in claim 5, wherein the ascertainment function ascertains a similarity measure of the input data to corresponding source data of the source data sets, which describes at least a similarity of the current measurement result of the input data set to the original measurement result of the source data set, wherein the ascertainment function retrieves the shim data of the source data set with the highest similarity measure from the database and outputs it as a shim parameter set of the output data set.

7. The method as claimed in claim 6, wherein the similarity measure also describes a similarity of the additional shim information.

8. The method as claimed in claim 6, wherein the similarity measure is modified by an optimization term, which relates to an additional optimization target at least partially described by the source data sets.

9. The method as claimed in claim 1, wherein a trained ascertainment function, which is trained using the source data sets of the database, is used.

10. The method as claimed in claim 1, further comprising:
before implementing the shim parameter set obtained as the output data set of the ascertainment function, ascertaining a comparison shim parameter set from the current measurement result using an optimization function that does not take into account magnetic influences at the respective operating location and is used to validate the shim parameter set of the ascertainment function.

11. A method for installing a magnetic resonance facility at an operating location, comprising:
ascertaining a shim parameter set with an ascertainment method as claimed in claim 1; and
setting up the shim facilities according to the shim parameter set.

12. The method as claimed in claim 11, further comprising:
after applying the shim parameters described by the output data set, evaluating, by a homogeneity condition, a new measurement result of a new magnetic field measurement;
if the homogeneity condition is not fulfilled by the new measurement result, iteratively improving the shim parameter set by analytically ascertaining a test shim parameter set in each iterative step from a previous measurement result using an optimization function which does not take into account magnetic influences at the respective operating location; and
after implementation of the test shim parameter set, performing a new magnetic field measurement; and
terminating the shim operation when a new measurement result fulfills the homogeneity condition.

13. An ascertainment facility for ascertaining a shim parameter set for shimming a magnetic resonance facility to improve homogeneity in a homogeneity volume, the ascertainment facility comprising:
an application unit configured to apply an ascertainment function to an input data set, at least comprising a current measurement result of a magnetic field measurement at the magnetic resonance facility to be shimmed, to ascertain an output data set comprising the shim parameter set; and
a usage unit configured to use a database to ascertain the shim parameter set using the ascertainment function, wherein source data sets are stored in the database for magnetic resonance facilities installed at an operating location for which a shim operation has been completed at the operating location, which source data sets comprise an original measurement result of a magnetic field measurement prior to the shim operation at the operating location and the shim parameters obtained as a final result of the shim operation at the operating location, which were ascertained taking into account magnetic influences at the respective operating location.

14. A non-transitory electronically readable data medium on which a computer program is stored, which, when executed on an ascertainment facility, causes the ascertainment facility to perform the steps of a method as claimed in claim 1.
